(19) United States
(12) Patent Application Publication
(10) Pub. No.: US 2017/0027060 A1
(43) Pub. Date: Jan. 26, 2017

(54) METHOD FOR FORMING ELECTRODE PATTERN ON SUBSTRATE BY LIGHT ANNEALING

(71) Applicants: GENERAL INTERFACE SOLUTION LIMITED, Miaoli County (TW); INTERFACE OPTOELECTRONIC (SHENZHEN) CO., LTD., SHENZHEN (CN)

(72) Inventors: TE-JEN TSENG, Zhubei (TW); CHIA-MING HSIEH, Zhubei (TW); TZU-HSIANG LIN, Zhubei (TW)

(21) Appl. No.: 14/966,890

(22) Filed: Dec. 11, 2015

(30) Foreign Application Priority Data
Jul. 21, 2015 (CN) 201510430304.6

(51) Int. Cl. H05K 3/06; G03F 7/20

(52) U.S. Cl. CPC H05K 3/061; G03F 7/20

(57) ABSTRACT

A method for forming electrode patterns on a substrate is disclosed. A layer of conductive materials is formed on the substrate, and a portion of the conductive materials is annealed by an exposing manner. The layer of conductive materials after being exposed includes an annealed first portion and an unannealed second portion. One of the annealed first portion or the unannealed second portion is removed from the substrate to form electrode patterns on the substrate.

### CROSS-REFERENCE TO RELATED APPLICATIONS

This application claims priority to Chinese Patent Application No. 201510430304.6 filed on Jul. 21, 2015, the contents of which are incorporated by reference herein.

### FIELD

The subject matter herein generally relates to a method for patterning conductive materials by using light annealing technologies.

### BACKGROUND

Transparent conductive materials such as indium tin oxides (ITO) are widely used in electronic devices to make electrode patterns due to their good performance, such as good conductivity, high light transmittance, and antiabrasion performance. A typical patterning method of the conductive materials employs a photo etching process (PEP) technology, which needs a plurality of steps including at least a cleaning process, a photoresist coating process, an exposing process, a developing process, and an etching process.

### BRIEF DESCRIPTION OF THE DRAWINGS

Implementations of the present technology will now be described, by way of example only, with reference to the attached figures.

FIG. 1 illustrates a diagrammatic view of a layer of conductive materials formed on a substrate in a process of forming electrode patterns according to a first embodiment.

FIG. 2 illustrates a diagrammatic, cross sectional view of the layer of conductive materials of FIG. 1 is exposed using a photomask.

FIG. 3 illustrates a diagrammatic, cross sectional view of a portion of the layer of conductive materials is removed from the substrate to form the electrode patterns on the substrate of FIG. 1.

FIG. 4 illustrates a diagrammatic, cross sectional view of one of the electrode patterns according to one embodiment.

FIG. 5 illustrates a diagrammatic, cross sectional view of one of the electrode patterns according to another embodiment.

FIG. 6 illustrates a diagrammatic, cross sectional view of a layer of conductive materials formed on a substrate in a process of forming electrode patterns according to a second embodiment.

FIG. 7 illustrates a diagrammatic, cross sectional view of the layer of conductive materials of FIG. 6 is exposed using a photomask.

FIG. 8 illustrates a diagrammatic cross sectional view of a portion of the layer of conductive materials is removed from the substrate to form the electrode patterns on the substrate of FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “coupled” is defined as connected, whether directly or indirectly through intervening components, and is not necessarily limited to physical connections. The connection can be such that the objects are permanently connected or releasably connected. The term “comprising”, when utilized, means “including, but not necessarily limited to”; it specifically indicates open-ended inclusion or membership in the so-described combination, group, series and the like.

The present disclosure is described in relation to a method for forming electrode patterns on a substrate using light annealing technologies. In summary, a layer of conductive materials is formed on the substrate, and a portion of the conductive materials is annealed by an exposing manner. The layer of conductive materials after being exposed includes an annealed first portion and an unannealed second portion. One of the annealed first portion and the unannealed second portion is removed from the substrate to form electrode patterns on the substrate. More details are provided below.

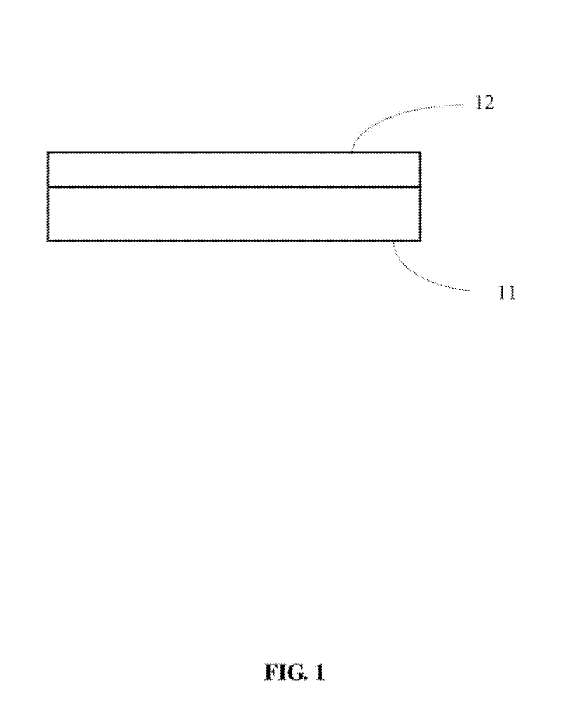

FIG. 1 to FIG. 3 illustrate a process of forming electrode patterns on a substrate 11 according to a first embodiment. The details of FIG. 1 to FIG. 3 are described as follow.

FIG. 1 illustrates a layer of conductive materials and a substrate according to the first embodiment. In at least one embodiment, a layer of conductive materials 12 is formed on the substrate 11. In at least one embodiment, the substrate 11 can be a transparent substrate, such as a glass substrate, a plastic substrate, or a flexible substrate. Some example of the substrate 11 can include, but not limited to, polycarbonate (PC) substrates, polyester (PET) substrates, cyclic olefin copolymer (COC) substrates, and thin glass substrates. In addition, before forming the conductive materials on the substrate 11, the substrate 11 can be cleaned using chemical solution (such as potassium hydroxide solution) to remove impurities and blots therefrom.

A thickness of the layer of conductive materials 12 formed on the substrate 11 is less than or equal to 50 nanometers (nm). The conductive materials 12 can be amorphous and transparent conductive materials, such as indium tin oxides (ITO), indium zinc oxides (IZO), aluminum zinc oxides (AZO), transparent films, or other similar materials.

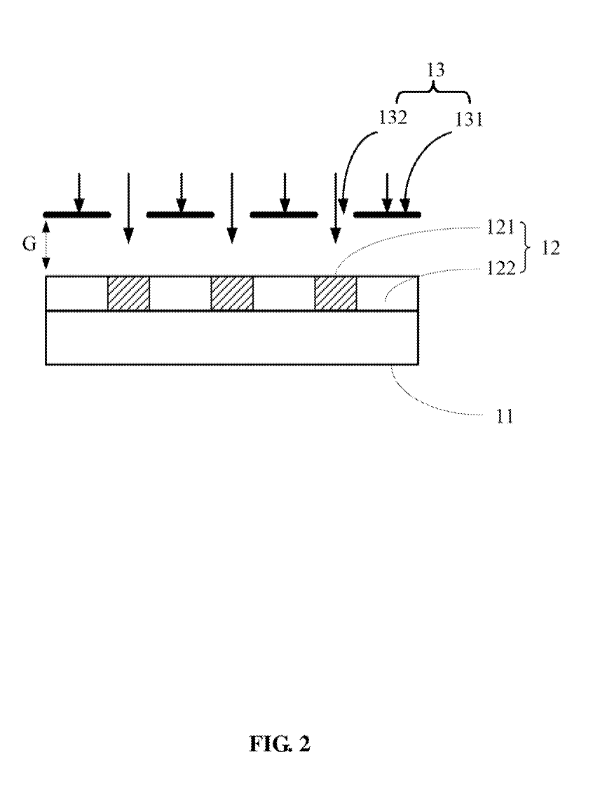

FIG. 2 illustrates the layer of conductive materials is exposed according to the first embodiment. In at least one embodiment, the layer of conductive materials 12 is exposed using a photomask 13 to anneal a portion of the layer of the conductive materials 12. In at lease one embodiment, the photomask 13 is located at a side of the conductive materials 12 opposite to the substrate 11. The photomask 13 and the layer of conductive materials 12 define a space G therebetween which is less than or equal to 100 micrometers (mm). The photomask 13 can be a hard mask which includes a plurality of light shielding portions 131 and a plurality of light transition portions 132. Each of the light transition portions 132 is located between two adjacent light shielding portions 131. The light shielding portions 131 utilized herein refers to a portion of the photomask 13 where the light can not pass therethrough. The light transition portions 132 utilized herein refers to the other portion of the photomask 13 where the light can pass therethrough.

In addition, light sources such as infrared light sources can be used to expose the layer of conductive materials 12. A portion of the light sources pass through the light transition portions 132 to anneal a portion of the conductive materials 12. Thus, the layer of conductive materials 12 includes a first portion 121 corresponding to the light transition portions 132 and a second portion 122 corresponding to the light shielding portions 131. The first portion 121 is annealed by the light sources because the light sources can pass through the light transition portions 132. The second portion is not annealed by the light sources because the light sources can not pass through the light shielding portions 131. The first portion gradually become microcrystal or poly-crystal during the exposing process of the conductive materials 12. A period of exposing time for the conductive materials 12 is less than 100 milliseconds (ms), and a power of the light sources is greater than one joule per square centimeter (J/cm²).

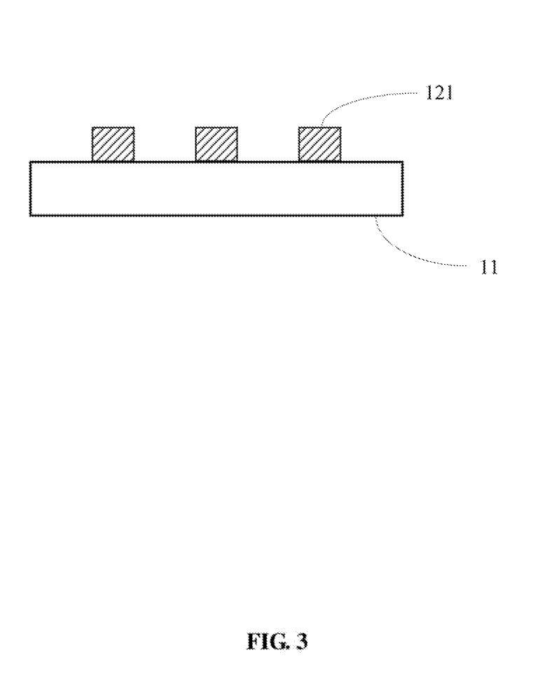

FIG. 3 illustrates the electrode patterns on the substrate according to the first embodiment. In at least one embodiment, one of the first portion 121 or the second portion 122 is removed from the substrate 11, to form electrode patterns on the substrate 11. In at least one embodiment, the layer of conductive materials 12 is etched to remove the second portion 122 which is not annealed. The annealed first portion 121 cannot be removed by the etching process thereby forming the electrode patterns on the substrate 11. Further, the first portion 121 has a surface resistance less than 180 ohm and an electro mobility greater than three cm²/(Vs). The electrode patterns formed on the substrate 11 can be utilized in smart phones, tablet computers, media players, or other similar devices. For example, the electrode patterns can be served as touch electrodes of a touch display device.

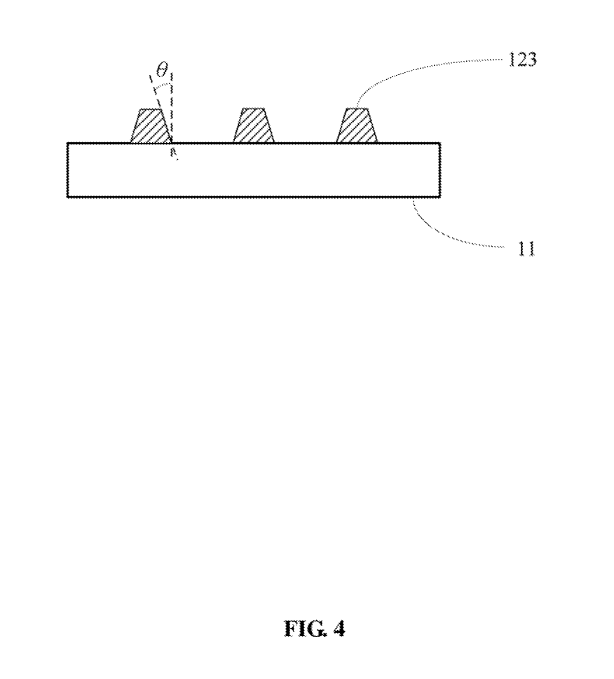

In other embodiments, a portion of the first portion 121 may be etched by the etching process of the layer of conductive materials 12, to form a plurality of electrode patterns 123 having a stepped shape as shown in FIG. 4. For example, the electrode pattern 123 can include an upper surface, a lower surface, and a bevel coupled between the upper surface and the lower surface. The bevel has an oblique angle less than 30 degrees. In at least one embodiment, the oblique angle refers to an angle formed between the bevel and a vertical surface perpendicular to the upper surface or the lower surface. Further, a width of the upper surface is less than a width of the lower surface.

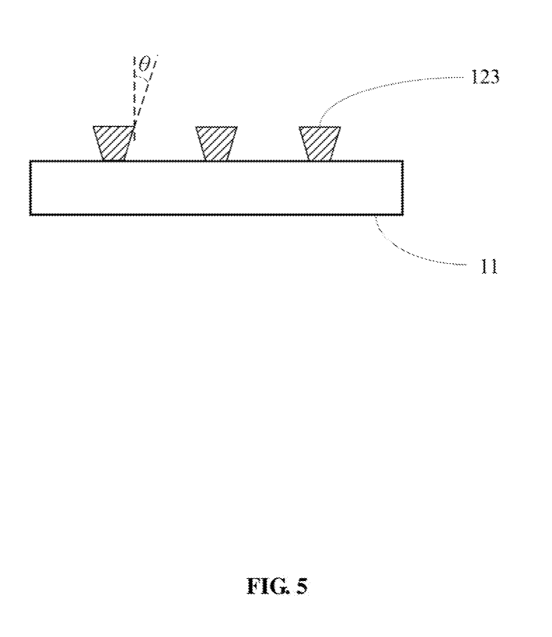

In other embodiments, as shown in FIG. 5, the width of the upper surface of the electrode pattern 123 can be greater than the width of the lower surface of the electrode pattern 123.

Further, it is understood that, in other embodiments, the electrode patterns on the substrate 11 can be formed by removing the annealed first portion 122 of the layer of the conductive materials 12 using other feasible technologies. Thus, the electrode patterns are formed by the second portion 122 of the conductive materials 12 remained on the substrate 11.

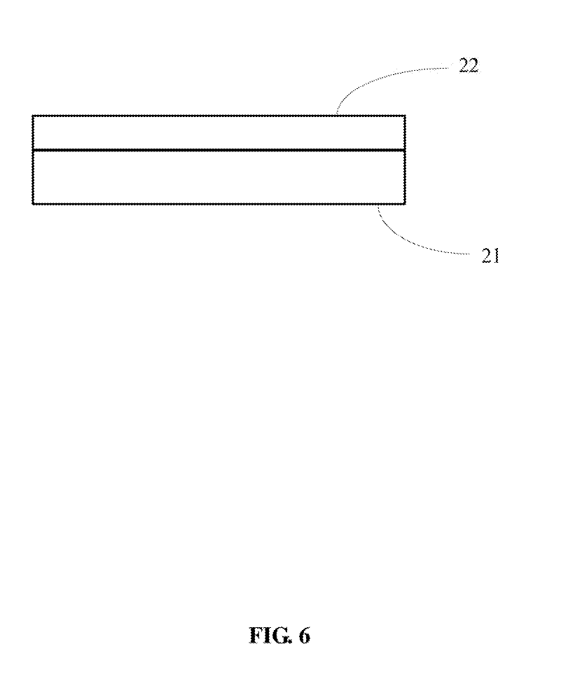

FIG. 6 to FIG. 8 illustrate a process of forming electrode patterns on a substrate 21 according to a second embodiment. The details of FIG. 6 to FIG. 8 are described as follow.

FIG. 6 illustrates a layer of conductive materials and a substrate according to the second embodiment. In at least one embodiment, a layer of conductive materials 22 is formed on the substrate 21. In at least one embodiment, the substrate 21 can be a transparent substrate, such as a glass substrate, a plastic substrate, or a flexible substrate. Some examples of the substrate 21 can include, but not limited to, polycarbonate (PC) substrates, polyester (PET) substrates, cyclic olefin copolymer (COC) substrates, and thin glass substrates. In addition, before forming the conductive materials on the substrate 21, the substrate 21 can be cleaned using chemical solution (such as potassium hydroxide solution) to remove impurities and blots therefrom.

A thickness of the layer of conductive materials 22 formed on the substrate 21 is less than or equal to 50 nanometers (nm). The conductive materials 22 can be amorphous and transparent conductive materials, such as indium tin oxides (ITO), indium zinc oxides (IZO), aluminum zinc oxides (AZO), transparent films, or other similar materials.

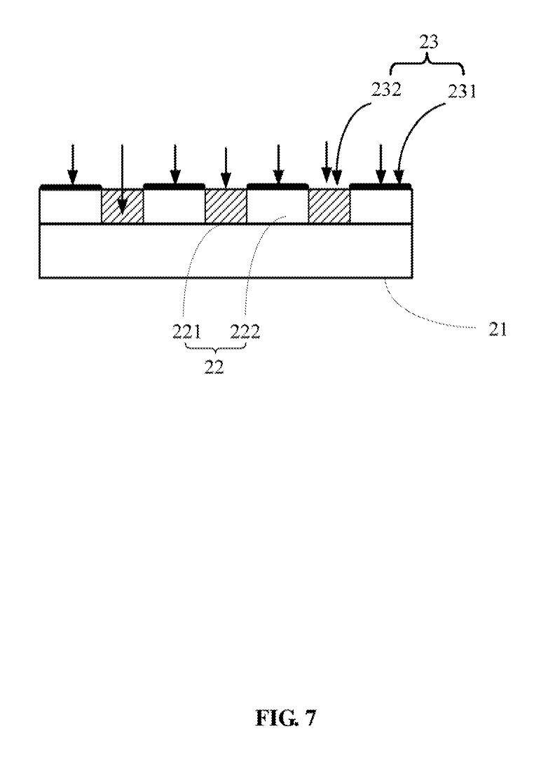

FIG. 7 illustrates the layer of conductive materials is exposed according to the second embodiment. In at least one embodiment, the layer of conductive materials 22 is exposed using a photomask 23 to anneal a portion of the layer of the conductive materials 22. In at lease one embodiment, the photomask 23 is located on a surface of the conductive materials 22 opposite to the substrate 21. Different from the first embodiment, the photomask 23 is contact with the surface of the layer of conductive materials 22. The photomask 23 can be formed by light shielding materials which are coated on the surface of the layer of conductive materials 22. For example, the light shielding materials can be ink and organic macromolecule polymer capable of preventing light to pass therethrough.

The photomask 23 can include a plurality of light shielding portions 231 and a plurality of light transition portions 232. Each of the light transition portions 232 is located between two adjacent light shielding portions 231. The light shielding portions 231 utilized herein refers to a portion of the photomask 23 where the light can not pass therethrough. The light transition portions 232 utilized herein refers to the other portion of the photomask 23 where the light can pass therethrough.

In addition, light sources such as infrared light sources can be used to expose the layer of conductive materials 22. A portion of the light sources pass through the light transition portions 232 to anneal a portion of the conductive materials 22. Thus, the layer of conductive materials 22 includes an annealed first portion 221 and an unannealed second portion 222. The annealed first portion 221 gradually become microcrystal state or poly-crystal state during the exposing process of the conductive materials 22. A period of exposing time for the conductive materials 22 is less than 100 milliseconds (ms), and a power of the light sources is greater than one joule per square centimeter (J/cm²).

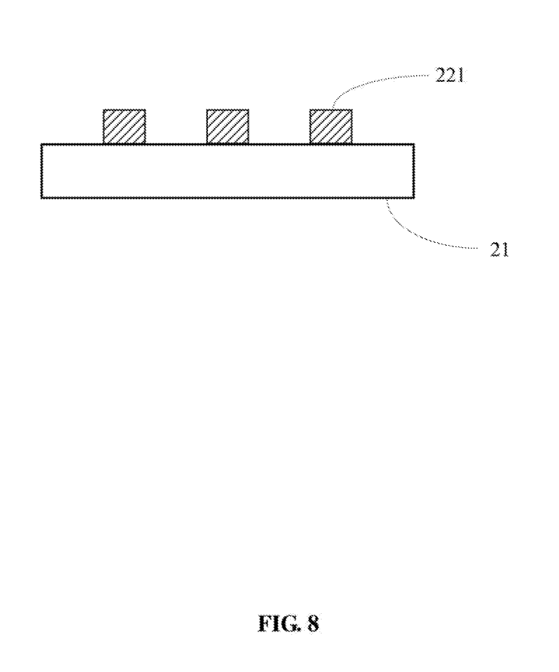

FIG. 8 illustrates the electrode patterns on the substrate according to the second embodiment. In at least one embodiment, one of the annealed first portion 221 or the unannealed second portion 222 is removed from the substrate 21, to form electrode patterns on the substrate 21. In at least one embodiment, the layer of conductive materials 22 is etched to remove the unannealed second portion 222. The annealed first portion 221 cannot be removed by the etching process thereby forming the electrode patterns on the substrate 21. Further, the annealed first portion 221 has a surface resistance less than 180 ohm and an electro mobility greater than three cm²/(Vs). The electrode patterns formed on the substrate 21 can be utilized in smart phones, tablet computers, media players, or other similar devices. For example, the electrode patterns can be served as touch electrodes of a touch display device.

In other embodiments, the electrode patterns on the substrate 21 can be formed by removing the annealed first portion 222 of the layer of the conductive materials 22 using other feasible technologies. Thus, the electrode patterns are formed by the second portion 222 of the conductive materials 22 remained on the substrate 21.

In the above described method of forming electrode patterns on a substrate, at least a photoresist coating process can be omitted. Therefore, the cost of manufacturing the electrode patterns can be reduced.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A method for forming electrode patterns on a substrate, comprising:
forming a layer of conductive materials on the substrate;
annealing a portion of the layer of conductive materials by exposing the layer of conductive materials, so that the layer of conductive materials comprise an annealed first portion and an unannealed second portion; and
removing one of the annealed first portion or the unannealed second portion to form electrode patterns on the substrate.

2. The method according to claim 1, wherein the layer of conductive materials is exposed using a photomask having a plurality of light shielding portions and a plurality of light transition portions.

3. The method according to claim 2, wherein the annealed first portion is corresponding to the light transition portions, and the unannealed second portion is corresponding to the light shielding portions.

4. The method according to claim 2, wherein the photomask is located at a side of the layer of conductive materials opposite to the substrate, the photomask and the layer of conductive materials define a space therebetween.

5. The method according to claim 4, wherein the space is less than or equal to 100 micrometers.

6. The method according to claim 2, wherein the photomask is located on and contact with a surface of the layer of conductive materials opposite to the substrate.

7. The method according to claim 6, wherein the photomask is formed by light shielding materials coated on the surface of the layer of conductive materials.

8. The method according to claim 1, wherein the light shielding materials comprise ink and organic macromolecule polymer.

9. The method according to claim 1, wherein the conductive materials are amorphous and transparent conductive materials.

10. The method according to claim 9, wherein the conductive materials become microcrystal or poly-crystal after being exposed.

11. The method according to claim 1, wherein the layer of conductive materials is exposed using light sources which are infrared light sources or near infrared light sources.

12. The method according to claim 11, wherein a period of exposing time for the layer of conductive materials is less than 100 milliseconds (ms), and a power of the light sources is greater than one joule per square centimeter (J/cm²).

13. The method according to claim 1, wherein removing one of the annealed first portion and the unannealed second portion comprises:
etching the layer of conductive materials to remove the unannealed second portion, wherein the electrode patterns are formed by the annealed first portion remained on the substrate.

14. The method according to claim 1, wherein each of the electrode patterns comprises an upper surface, a lower surface, and a bevel coupled between the upper surface and the lower surface, and the bevel has an oblique angle less than 30 degrees.
